(19) United States
(12) Patent Application Publication
(10) Pub. No.: US 2016/0071537 A1
(43) Pub. Date: Mar. 10, 2016

(54) FABRICATION OF BIT PATTERNED MEDIA USING MICROCONTACT PRINTING

(71) Applicant: HGST Netherlands B.V., Amsterdam (NL)

(72) Inventors: Thomas R. Albrecht, San Jose, CA (US); Xing-Cai Guo, Tracy, CA (US)

(21) Appl. No.: 14/945,303

(22) Filed: Nov. 18, 2015

Related U.S. Application Data
(62) Division of application No. 13/251,125, filed on Sep. 30, 2011.

(51) Int. Cl. G11B 5/851; C23C 14/08; C23C 14/02; C23C 14/14; C23C 14/12; C23C 14/34; C23C 14/10

(52) U.S. Cl. CPC G11B 5/851; C23C 14/34; C23C 14/08; C23C 14/10; C23C 14/14; C23C 14/12; C23C 14/024

(57) ABSTRACT

A method for manufacturing a bit patterned magnetic media for magnetic data recording. The method includes selectively depositing a self assembled monolayer over a seed layer and then oxidizing the deposited self assembled monolayer. The self-assembled monolayer can be deposited by use of a stamp to form a pattern covering areas where a non-magnetic segregant (such as an oxide) is to be formed and openings where a magnetic material is to be formed. A magnetic alloy and a segregant (such as an oxide) are then co-sputtered. The magnetic alloy grows only or selectively over the seed layer, whereas the segregant grows only or selectively over the oxidized self-assembled monolayer.

### RELATED APPLICATIONS

The present Patent Application is a Divisional Application of commonly assigned U.S. patent application Ser. No. 13/251,125, entitled, FABRICATION OF BIT PATTERNED MEDIA USING MICROCONTACT PRINTING, filed Sep. 30, 2011.

### FIELD OF THE INVENTION

The present invention relates to magnetic data recording and more particularly to bit patterned media and to a method for manufacturing such a media using micro-contact printing to control oxide and magnetic layer formation during deposition.

### BACKGROUND OF THE INVENTION

A key component of a computer is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located on a slider that has an air bearing surface (ABS). When the slider rides on the air bearing, the write and read heads are employed for writing magnetic impressions to and reading magnetic impressions from the rotating disk. The read and write heads are connected to processing circuitry that operates according to a computer program to implement the writing and reading functions.

As the data density of magnetic recording systems increases, it becomes necessary to fit more bits of ever smaller size closer together on a magnetic media. When the data density becomes too large, the grains of the magnetic media become so small that they become thermally unstable. One way to mitigate this is to construct the media as a bit patterned media. Such a media includes individual isolated magnetic islands that are separated by non-magnetic material or non-magnetic spaces. Developments to produce such bit patterned media have proven to be expensive and time consuming for use in a manufacturing environment. In addition, the ability to construct such a bit patterned media at high data density has run in to manufacturing limitations such as with regard to the lithographic processes and other processes used to construct such a media. Therefore, there remains a need for a process for manufacturing a bit patterned media in a cost and time efficient manner that can produce a bit patterned media having a high data density.

### SUMMARY OF THE INVENTION

The present invention provides a method for manufacturing a magnetic media that includes depositing a seed layer and forming a stamp having a pattern formed thereon. The stamp is coated with a segregant promoter material, and the stamp is placed against the seed layer so as to print the segregant promoter material onto the seed layer. A co-sputtering of a magnetic material and a segregant material is then performed.

The segregant promoter can be a self-assembled monolayer material, which can be a hydrocarbon polymer with silane and thiol termination such as HS—(CH₂)ₙ—Si(X)₃, where n>2 and X is Cl or OCH₃. When this material is oxidized such as by ultraviolet (UV)/ozone exposure, the subsequent co-sputtering causes the magnetic material to grow preferentially (or selectively) over the seed layer and causes the non-magnetic segregant (e.g. oxide) to grow preferentially (or selectively) over the segregant promoter layer.

This process for forming a bit patterned media eliminates the need for costly, time consuming etching processes to define the location of magnetic islands on the media and also avoids potential damage to the magnetic media that might arise from the use of such etching.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is a top down view of a portion of a bit patterned media according to an embodiment of the invention;

FIG. 3 is a view of a magnetic media in an intermediate stage of manufacture, having a soft magnetic under-layer and a seed layer;

FIG. 4 is a view of a stamp for use in a method of the present invention;

FIG. 5 is a top down perspective view of the stamp of FIG. 4;

FIG. 6 is a view of the stamp of FIG. 5 with a layer of segregant promoter material coated thereon;

FIG. 7 is a view illustrating a stamping process wherein a segregant promoter material is selectively applied to the magnetic media under-layer and seed layer of FIG. 3;

FIG. 8 is a view of the magnetic media under-layer and seed layer with the segregant promoter layer selectively applied;

FIG. 9 is a top down view of the structure of FIG. 8;

FIG. 10 is a view of a magnetic media having a bit pattern formed thereon by a method of the present invention; and

FIGS. 11 and 12 are views illustrating a possible method for manufacturing a stamp for use in a method according to the invention.

### DETAILED DESCRIPTION OF THE PREFERRED EMBODIMENTS

The following description is of the best embodiments presently contemplated for carrying out this invention. This description is made for the purpose of illustrating the general principles of this invention and is not meant to limit the inventive concepts claimed herein.

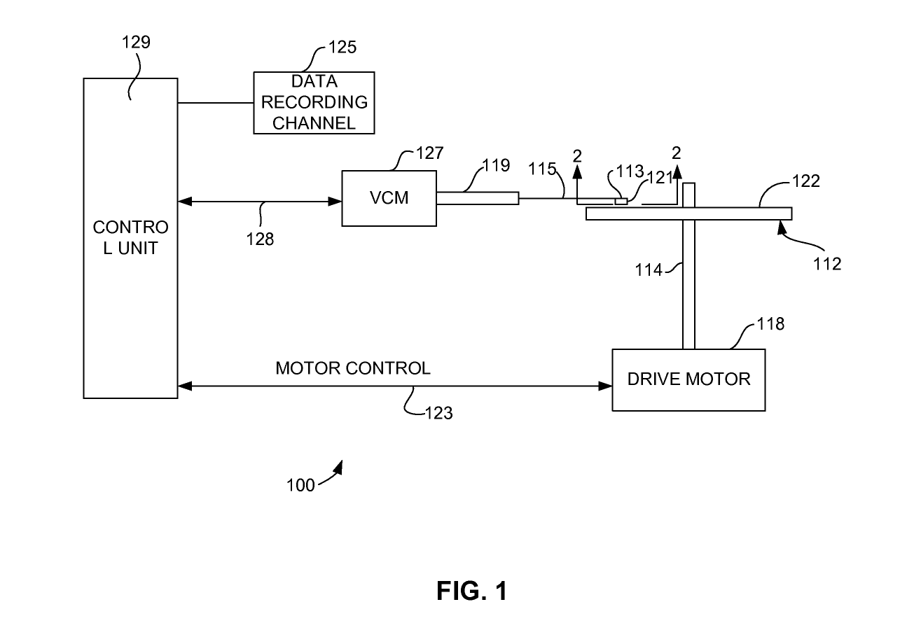

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 can access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122 which exerts an upward force or lift on the slider. The air bearing thus counter-balances the slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

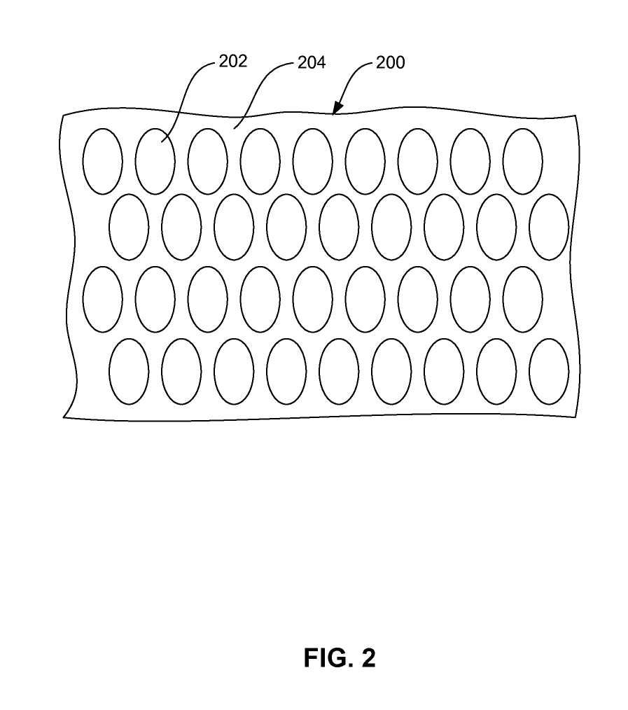

FIG. 2 shows a top down view of a portion of a magnetic media that can be constructed according to a method of the present invention. In FIG. 2 it can be seen that the magnetic media 200 has magnetic islands 202 that are separated by non-magnetic segregant material 204. The magnetic islands 202 can be constructed of a material such as an alloy containing cobalt and platinum, and the non-magnetic segregant can be an oxide such as SiO₂.

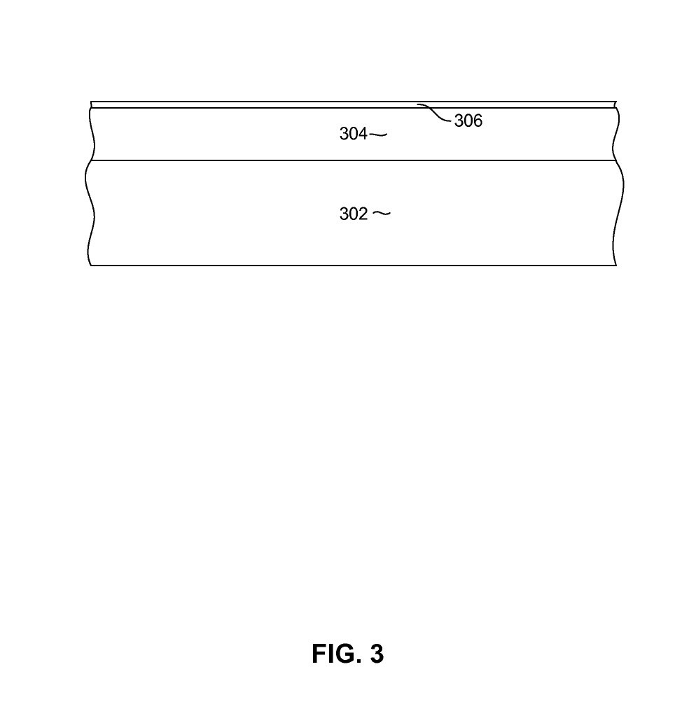

FIGS. 3-10 illustrate a method for manufacturing a magnetic media according to an embodiment of the invention. With particular reference to FIG. 3, a substrate 302 is provided. This substrate 302 can be a glass substrate or aluminum alloy that has been polished to have a very smooth surface. A soft magnetic layer 304 is deposited over the substrate 302. The soft magnetic layer 304 is a material having a low magnetic coercivity and may actually be constructed as a lamination of one or more magnetic layers separated by thin non-magnetic layers. After the soft magnetic layer 304 has been deposited over the substrate 302, a seed layer 306 is deposited over the soft magnetic layer 304. The seed layer is a material that is suitable for the growth of large-grain magnetic alloys thereon, and can be Ru deposited by low pressure sputter deposition. The seed layer 306 can also be a lamination of several layers.

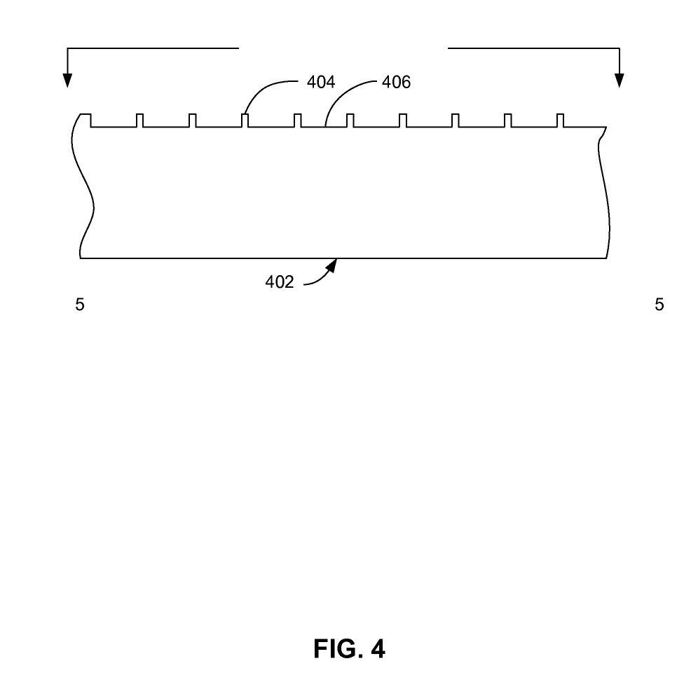

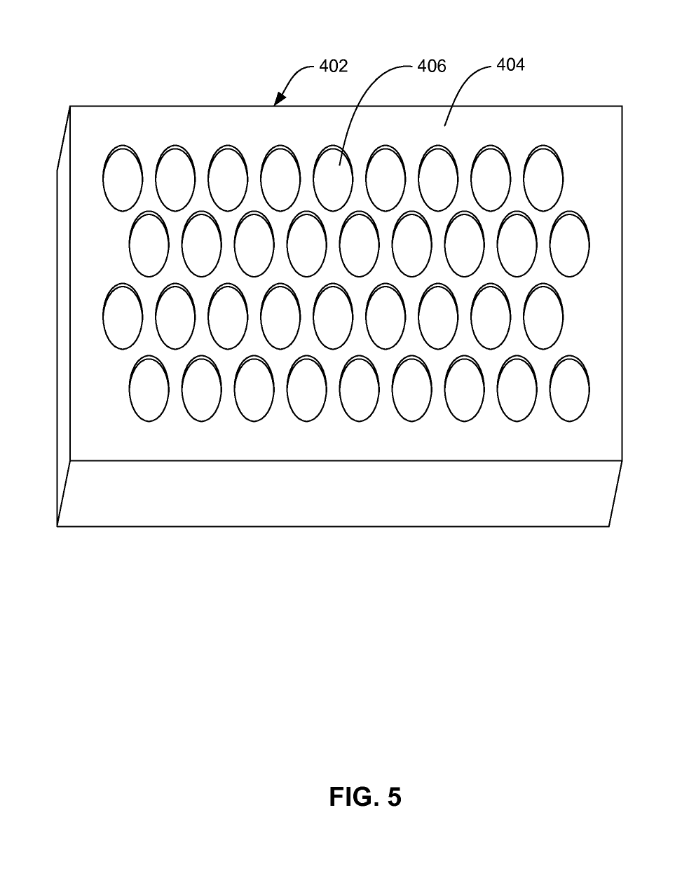

With reference to FIG. 4, a stamp 402 is formed having raised portions 404 and recessed portions 406. FIG. 5 shows a top down perspective view of the structure of FIG. 4, as seen from line 5-5 of FIG. 4. In FIG. 5 it can be seen that the recesses 406 can be formed as circular or elliptical recesses 406 that are separated by raised portions. These recesses 406 will define an area where a magnetic island will be formed on the magnetic media, as will be seen. Although the recesses 406 are shown as being elliptical in FIG. 5, this is by way of example. They could be formed in other shapes, such as circles or rectangles if desired.

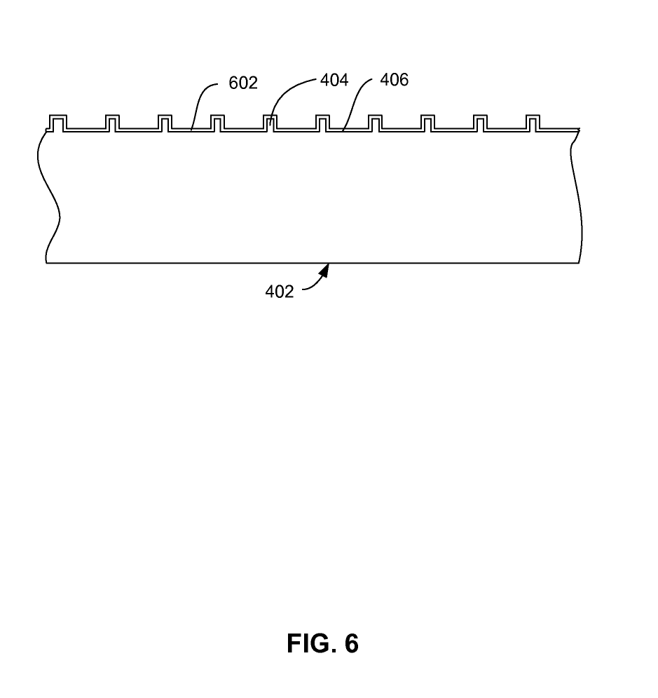

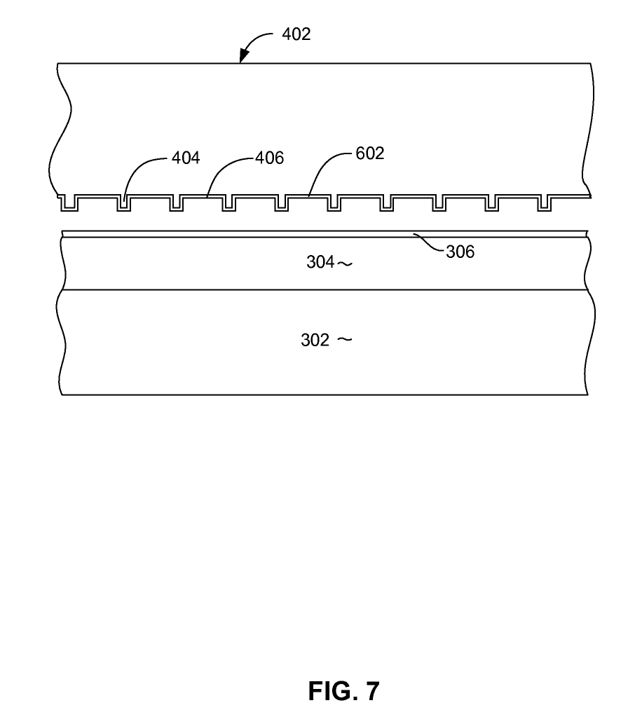

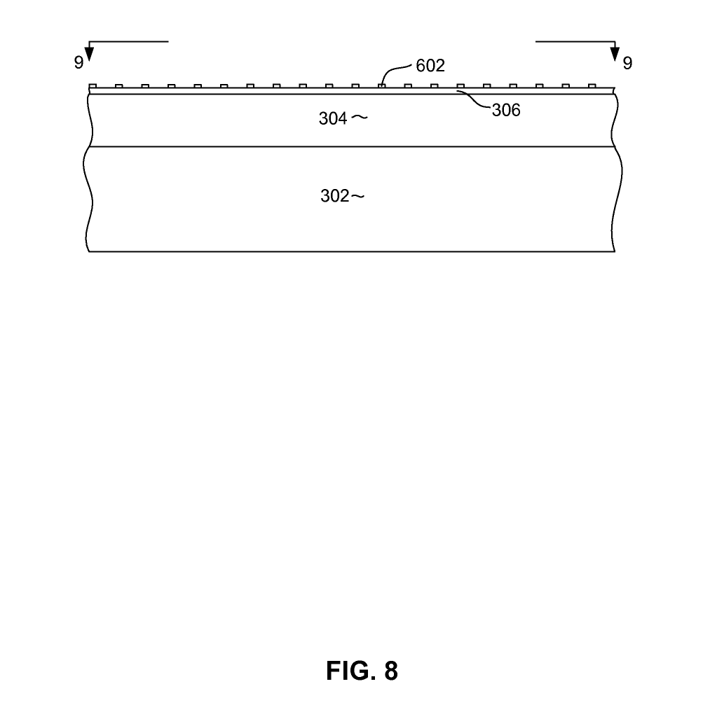

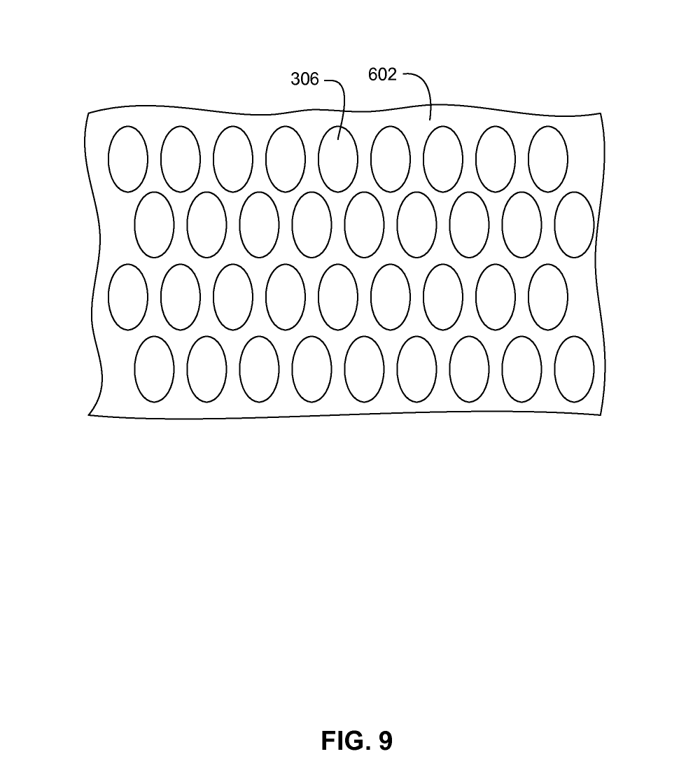

With reference now to FIG. 6, a very thin, continuous layer of a segregant promoter material 602 is coated onto the stamp 402. The segregant promoter material 602 is a material that causes the preferential growth of a segregant during sputter deposition. The segregant promoter material can be a material that can form an oxide like material. For example, the segregant promoter material 602 can be a material such as a self-assembled monolayer (SAM) material 602 that can later be treated so as to form an oxide like material. This layer 602 is a material that will cause an oxide to selectively grow on it, and for purposes of simplicity will be referred to herein simply as a segregant promoter 602. The segregant promoter 602 is preferably applied very thin and may be (but is not necessarily) a mono-layer. The coating of the segregant promoter material 602 onto the stamp 402 can be accomplished by immersing the stamp 402 in a liquid or by exposing the stamp 402 to a vapor containing an appropriate precursor material. Then, as illustrated in FIG. 7, the stamp 402 is pressed against the seed layer 306 to print the segregant promoter material 602 onto the seed layer 306 in a specific pattern. This selectively deposits the segregant promoter 602 onto the seed layer 306 only at the locations of the raised portions 404 of the stamp, leaving selectively deposited segregant promoter 602 on the seed layer 306 as shown in FIGS. 8 and 9, wherein FIG. 8 shows a cross sectional view and FIG. 9 shows a top down view as seen from line 9-9 of FIG. 8.

The segregant promoter 602 can be a hydrocarbon polymer with silane and thiol termination such as HS—(CH₂)ₙ—Si(X)₃, where n>2, and X is Cl or OCH₃. The stamp 402 can be constructed of SiO₂/polydimethylsiloxane (PDMS) (as will be discussed below). The segregant promoter layer 602 which can be a thiol-terminated organosilane may be deposited onto the SiO₂/PDMS stamp surface by either wet chemical or dry vapor-phase methods. In the wet chemical method, the stamp is dipped into a 1 mM solution of the organosilane in toluene. Extra physisorbed and unattached molecules are removed by repeated rinsing in pure toluene. Vapor phase silylation is performed at 100 degrees C. in a vacuum oven. If necessary to remove excess material, the vacuum can be maintained for additional time in order to evaporate extra physisorbed molecules from the surface.

If the segregant promoter material 602 is a self-assembled monolayer such as that described above, the patterned segregant promoter 602 can be converted to an oxide like state through a UV/ozone exposure process. Such a process is illustrated by Y. Zhang, et al., J. Am. Chem. Soc., vol. 120 pp. 2654-2655 (1998), which is incorporated herein by reference. UV/ozone cleaning ovens (e.g. UVOCS) may be used for initial tests. UV tools currently used for lubricant bonding in media manufacturing may be used with nitrogen purge turned off and with ventilation installed for ozone disposal. Other materials 602, and other conversion methods, such as exposure to plasma, electrons or heat may also be used, as long as a chemical contrast pattern is produced that causes selective growth of the media segregant around the islands of magnetic film in the target pattern.

Optionally, the exposed seed layer 306 can be cleaned or reduced to remove an oxide layer. This can be accomplished by light sputtering or ion milling. These processes, however, may not be sufficiently selective so they must be carefully performed so as not to damage or remove the segregant promoter layer 602. Another option is exposure to H⁺ plasma, which can reduce oxidized metals back to the metallic state, but may be selective enough not to damage the patterned segregant promoter material 602.

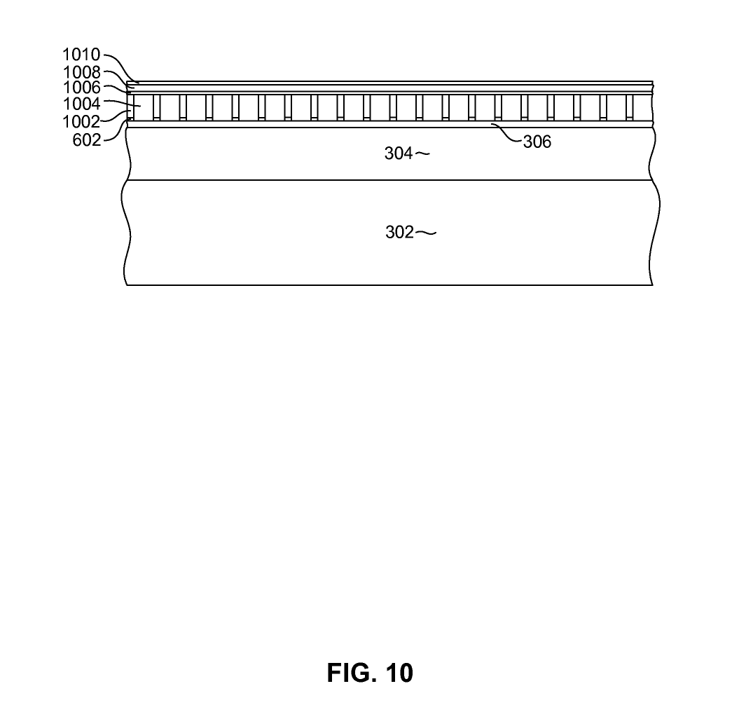

With reference now to FIG. 10, media growth proceeds with co-sputtering of magnetic alloy 1004 and segregant 1002. That is, both a magnetic alloy 1004 and a segregant 1002 are simultaneously sputter deposited in a sputter deposition tool. The magnetic alloy 1004 can be alloy containing Co and Pt or and the segregant 1002 can be and oxide such as SiO₂. The segregant 1002 grows preferentially over the patterned segregant promoter 602, and the magnetic alloy 1004 forms islands that grow only over the exposed seed layer 306. The net result is that the anti-dot pattern stamped on the disk with the segregant promoter 602 is replicated in the growth of the magnetic alloy 1004 and co-sputtered segregant 1002. The magnetic alloy 1004 grows as isolated islands over the exposed seed layer 306, and the segregant 1002 grows on the anti-dot pattern, forming a network around these islands. Both materials (magnetic alloy 1004 and segregant 1002) grow substantially vertically from the template, exposing both materials with the proper pattern at the newly formed upper surface.

The magnetic alloy 1004 (which can be referred to as a “storage layer” since it stores the magnetic bit of information) can actually include various magnetic materials. For example, the magnetic material 1004 can be several layers of materials each having different magnetic properties, such as each having a different magnetic coercivity. The magnetic layer 1004 can be constructed as a multi-layer structure with fine laminations of CoPt and/or CoPd. The magnetic layer 1004 can also be constructed as an exchange spring structure with a high magnetic coercivity layer, a low magnetic coercivity layer and a thin, non-magnetic coupling layer between the high and low coercivity layers. Again, whatever structure is used for layer 1004, this magnetic material is deposited simultaneously (co-sputtered) with the segregant material 1002.

With continued reference to FIG. 10, after the magnetic alloy 1004 and segregant 1002 have been deposited as described above, other media layers can be deposited. These can include an exchange control layer 1006 deposited over the magnetic alloy 1004 and segregant 1004, a capping layer 1008 can be deposited over the exchange control layer 1006 and an optional protective layer 1010 formed over the capping layer 1008. The exchange control layer can be a material such as Ru. The capping layer 1008 can be an alloy containing Co and other materials. The protective coating layer 1010 can be a physically hard material such as Diamond-Like Carbon (DLC) and serves to protect the under-lying layers from damage during operation of the media in a disk drive, such as from damage that might occur from head disk contact (e.g. crashing).

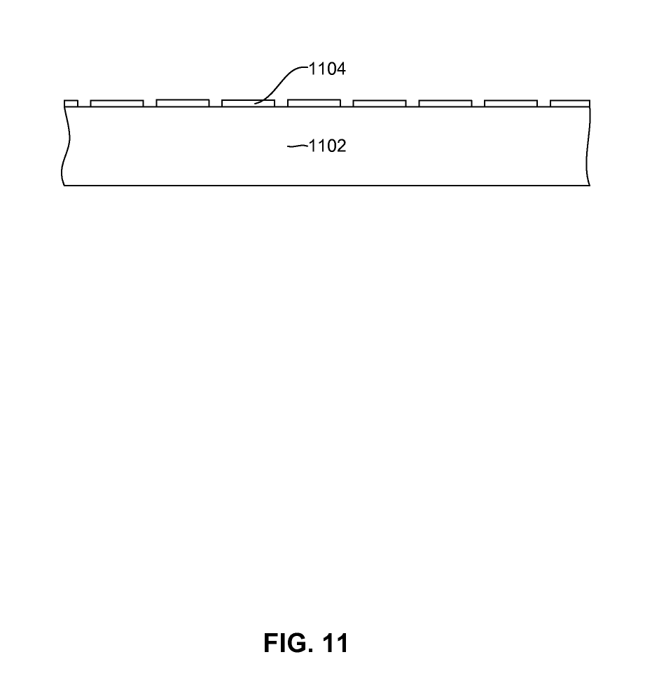

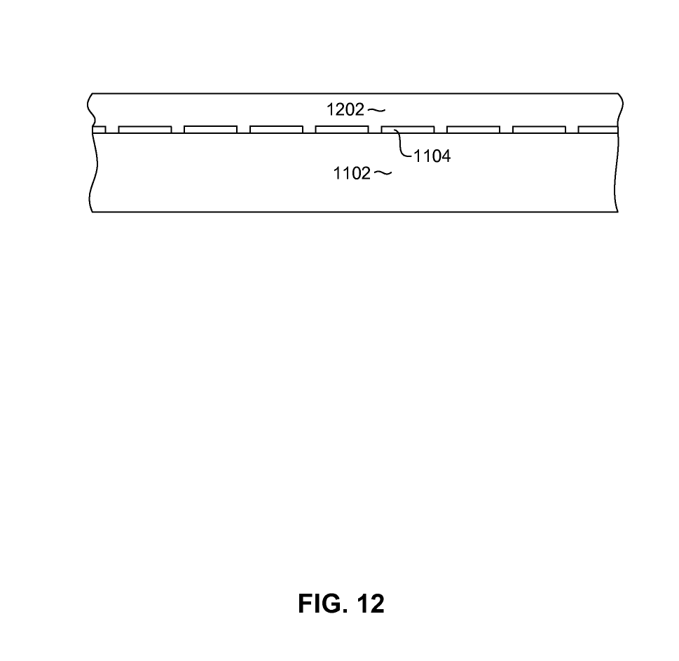

FIGS. 11 and 12 illustrate a possible method for constructing a stamp, such as the stamp 402 of FIG. 5. This is, however, by way of example, as other methods could be used to construct such a mask. With reference to FIG. 11, a master substrate 1102 is provided. This could be a Si substrate. A relief pattern is then formed on the surface of the substrate. One way to accomplish this is to pattern a material 1104 of desired thickness over the surface of the substrate 1102. This material 1104 can be lithographically patterned such as by etching or some other process. This patterned material, could be, for example, SiO₂, Si₃N₄, a metal, photoresist, or wax. As can be seen, this provides a relief pattern having raised portions and recessed portions. This pattern of raised and recessed portions is a negative image of the desired pattern of the completed stamp. This negative pattern could also be formed in other ways, such as by masking and then performing a reactive etching or ion milling to remove exposed portions of the substrate material 1102.

Then, with reference to FIG. 12, a material 1202 that will become the stamp is coated onto the master die layers 1102, 1104. This material 1202 can be a liquid silicone rubber precursor material such as PDMS precursor. A thermal or UV curing process can then be performed to form the material 1202 into a solid stamp structure, which can then be lifted off of the master (1102, 1104).

It should be pointed out, that the above process has been discussed as specifically applied to constructing a magnetic media for magnetic date recording. However, the process of selectively co-sputtering an array of structures from a stamp printed base material can also be used in other applications as well. For example, such a method can be useful in the construction of an array of cells of in a nonvolatile cross-point memory. Other examples of possible applications include the formation of array of cells of a phase change material in a dielectric matrix, such as might be useful in the construction of a memory cell. The process could also be applied to the construction of an array of cells of a memristor material in a dielectric matrix, which could also be useful in the construction of a memory cell array. The process could also be useful in the construction of an array of electrically conductive vias in a dielectric matrix or to the construction of an array of Magnetic Random Access Memory (MRAM) cells in a dielectric matrix. In order for the above described process to be effectively implemented, the structures being constructed should be fairly uniformly distributed over an area of interest, and all of the features should be below a critical feature size. The above segregation only occurs over a certain limited length scale.

While various embodiments have been described above, it should be understood that they have been presented by way of example only and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a magnetic media, comprising:
depositing a seed layer;
forming a stamp having a pattern formed thereon;
coating the stamp with a segregant promoter;
placing the stamp against the seed layer so as to selectively print the segregant promoter onto the seed layer; and
performing a co-sputtering of a magnetic material and a segregant.

2. The method as in claim 1 wherein the segregant promoter comprises a self-assembled monolayer.

3. The method as in claim 1 wherein the seed layer comprises Ru.

4. The method as in claim 1 wherein the segregant promoter comprises a hydrocarbon polymer with silane and thiol termination.

5. The method as in claim 1 wherein the segregant promoter comprises a thiol terminated organosilane.

6. The method as in claim 1 wherein the magnetic material comprises a plurality of layers of differing magnetic properties.

7. The method as in claim 1 wherein the co-sputtered segregant comprises an oxide.

8. The method as in claim 1 wherein the seed layer comprises Ru deposited by low pressure sputter deposition.

9. The method as in claim 1 further comprising, after printing the segregant promoter, and before co-sputtering the magnetic material and the segregant, treating the segregant promoter to make it an oxide-like material.

10. The method as in claim 9 wherein the treatment of the segregant promoter to form an oxide-like material comprises UV and/or ozone exposure.

11. The method as in claim 1 wherein the co-sputtered segregant comprises SiO₂.

12. The method as in claim 1 further comprising after performing the co-sputtering of the magnetic material and the segregant, depositing an exchange control layer followed by a capping layer.

13. The method as in claim 1 further comprising after performing the co-sputtering of the magnetic material and the segregant, depositing a protective layer.

14. A method for manufacturing a structure, comprising:
depositing a seed layer;
forming a stamp having a pattern formed thereon;
coating the stamp with a segregant promoter;
placing the stamp against the seed layer so as to selectively print the segregant promoter onto the seed layer; and
performing a co-sputtering of a first material and a segregant.

15. The method as in claim 14 wherein the pattern formed on the stamp includes recessed portions configured to define a magnetic feature and raised portions configured to define a non-magnetic feature.

16. The method as in claim 14 wherein the segregant promoter comprises a hydrocarbon polymer with silane and thiol termination.

17. The method as in claim 14 wherein the segregant promoter comprises HS—(CH₂)ₙ—Si(X)₃, where n>2 and X is Cl or OCH₃.

18. The method as in claim 14 wherein the pattern is configured to define an array of magnetic cells of a non-volatile memory.

19. The method as in claim 14 wherein the pattern is configured to define an array of phase change material cells in a dielectric matrix.

20. The method as in claim 14 wherein the pattern is configured to define an array of memristor cells in a dielectric matrix.

21. The method as in claim 14 wherein the pattern is configured to define an array of electrically conductive vias in a dielectric matrix.
